(19) United States
(12) Patent Application Publication
(10) Pub. No.: US 2025/0364454 A1
(43) Pub. Date: Nov. 27, 2025

(54) BONDING USING TRANSPARENT CONDUCTIVE MATERIALS AND TRANSPARENT DIELECTRIC MATERIALS

(71) Applicant: ADEIA SEMICONDUCTOR BONDING TECHNOLOGIES INC., San Jose, CA (US)

(72) Inventors: Gaius Gillman Fountain, Jr., Youngsville, NC (US); Belgacem Haba, Saratoga, CA (US); Rajesh Katkar, Milpitas, CA (US); Oliver Zhao, Sunnyvale, CA (US)

(21) Appl. No.: 18/902,577

(22) Filed: Sep. 30, 2024

Related U.S. Application Data
(60) Provisional application No. 63/650,783, filed on May 22, 2024.

(51) Int. Cl. H01L 23/00; H01L 25/16

(52) U.S. Cl. CPC H01L 24/05; H01L 24/03; H01L 24/08; H01L 24/80; H01L 25/167; H01L 2224/0345; H01L 2224/03452; H01L 2224/03614; H01L 2224/05073; H01L 2224/05187; H01L 2224/05647; H01L 2224/05687; H01L 2224/08145; H01L 2224/80895; H01L 2224/80896; H01L 2224/80948; H01L 2924/05432; H01L 2924/0544

(57) ABSTRACT

A structure includes a substrate having a device with first and second sides generally opposite to one another, at least one dielectric layer at least partially overlying the second side of the device, and a conduit extending through the at least one dielectric layer to transmit electrical signals and optical signals through the at least one dielectric layer to and/or from the device. The conduit includes an electrically conductive and optically transmissive first portion and an electrically insulative and optical transmissive second portion. The first portion is in electrical communication with the second side of the device and is substantially overlying the second portion.

### BACKGROUND

### Field

The field relates to systems and methods for wafer-to-wafer, die-to-die, and/or die-to-wafer hybrid bonding for semiconductor devices and optoelectronic devices.

### Description of the Related Art

Semiconductor elements, such as semiconductor wafers or integrated device dies, can be stacked and directly bonded to one another without an adhesive, thereby forming a bonded structure. Nonconductive (e.g., dielectric; semiconductor) surfaces can be made extremely smooth and treated to enhance direct, covalent bonding, even at room temperature and without application of pressure beyond contact. In some hybrid bonded structures, nonconductive field regions of the elements can be directly bonded to one another, and corresponding conductive contact structures can be directly bonded to one another.

For example, a semiconductor element can be mounted to a carrier, such as a package substrate, an interposer, a reconstituted wafer or element, a flat panel, a glass, etc. A semiconductor element can be stacked on top of the semiconductor element (e.g., a first integrated device die can be stacked on a second integrated device die). Each of the semiconductor elements can have conductive pads for mechanically and electrically bonding the semiconductor elements to one another with the conductive pads mechanically and electrically bonded to one another.

### SUMMARY

In certain implementations, a structure comprises a substrate comprising a device having first and second sides generally opposite to one another, at least one dielectric layer at least partially overlying the second side of the device, and a conduit extending through the at least one dielectric layer to transmit electrical signals and optical signals through the at least one dielectric layer to and/or from the device. The conduit comprises an electrically conductive and optically transmissive first portion and an electrically insulative and optical transmissive second portion. The first portion is in electrical communication with the second side of the device and is substantially overlying the second portion.

In certain implementations, an apparatus comprises a first structure and a second structure. The first structure comprises a substrate comprising a device, at least one first dielectric layer at least partially overlying the device, and a first conductive feature. The first conductive feature comprises an electrically conductive and optically transmissive first portion, and an electrically insulative and optical transmissive second portion. The first portion is in electrical communication with the device and substantially overlying the second portion. The second structure comprises a second conductive feature bonded to the first conductive feature of the first structure.

In certain implementations, a method comprises providing an initial structure comprising a substrate, a device having an interface, and at least one first dielectric layer overlying the substrate and the interface of the device. The method further comprises patterning and etching a recess through the at least one first dielectric layer extending from an outer surface of the at least one first dielectric layer to the interface. The method further comprises depositing at least one first layer comprising at least one electrically conductive and optically transmissive material over the at least one first dielectric layer, over the device, and onto sidewalls within the recess. The method further comprises depositing at least one second layer comprising at least one electrically insulative and optically transmissive material over the at least one first layer. The method further comprises planarizing the at least one first layer and the at least one second layer. The method further comprises depositing at least one second dielectric layer over the at least one first layer, the at least one second layer, and the at least one first dielectric layer. The method further comprises patterning and etching a second recess through the at least one second dielectric layer extending from an outer surface of the at least one second dielectric layer to the at least one first layer and the at least one second layer. The method further comprises depositing at least one third layer comprising the at least one electrically conductive and optically transmissive material over the at least one first layer and the at least one second layer within the second recess and over the outer surface of the at least one second dielectric layer. The method further comprises planarizing the at least one third layer.

In certain implementations, a method comprises providing a first structure comprising a substrate, at least one first dielectric layer at least partially overlying the device, and a first conductive feature comprising an electrically conductive and optically transmissive first portion and an electrically insulative and optical transmissive second portion. The method further comprises hybrid bonding a second structure to the first structure, including directly bonding at least one second dielectric layer to the at least one first dielectric layer and directly bonding a conductive feature of the second structure to the electrically conductive and optically transmissive first portion.

### BRIEF DESCRIPTION OF THE DRAWINGS

Specific implementations will now be described with reference to the following drawings, which are provided by way of example, and not limitation.

FIG. 1A is a schematic cross-sectional side view of two elements prior to bonding in accordance with certain implementations described herein.

FIG. 1B is a schematic cross-sectional side view of the two elements of FIG. 1A after bonding in accordance with certain implementations described herein.

FIG. 2 schematically illustrates a cross-sectional view of an example structure in accordance with certain implementations described herein.

FIG. 3 schematically illustrates a cross-sectional view of the example structure of FIG. 2 bonded to a second structure in accordance with certain implementations described herein.

FIG. 4 is a plot of the refractive index of Al₂O₃ as a function of wavelength in a range of about 200 nm to about 2500 nm in accordance with certain implementations described herein.

FIG. 5 is a flow diagram of an example method for forming a structure compatible with certain implementations described herein.

FIGS. 6A-6H schematically illustrate various structures formed during an example of the method 500 for forming the example structure of FIG. 2 in accordance with certain implementations described herein.

### DETAILED DESCRIPTION

Various implementations disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some implementations, nonconductive bonding layers can be blanket deposited over the base substrate portions without being patterned with conductive features (e.g., without pads). In other implementations, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various implementations, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some implementations, the dielectric materials at the bonding surface do not comprise polymer materials, such as epoxy (e.g., epoxy adhesives, cured epoxies, or epoxy composites such as FR-4 materials), resin or molding materials.

In other implementations, the bonding layers can comprise an electrically conductive material, such as a deposited conductive oxide material, e.g., indium tin oxide (ITO), as disclosed in U.S. patent application Ser. No. 18/391,173, filed Dec. 20, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other implementations, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in implementations that utilize a nitrogen plasma for activation, a nitrogen concentration peak can be formed at the bond interface. In some implementations, the nitrogen concentration peak may be detectable using secondary ion mass spectroscopy (SIMS) techniques. In various implementations, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In implementations that utilize an oxygen plasma for activation, an oxygen concentration peak can be formed at the bond interface between non-conductive bonding surfaces. In some implementations, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

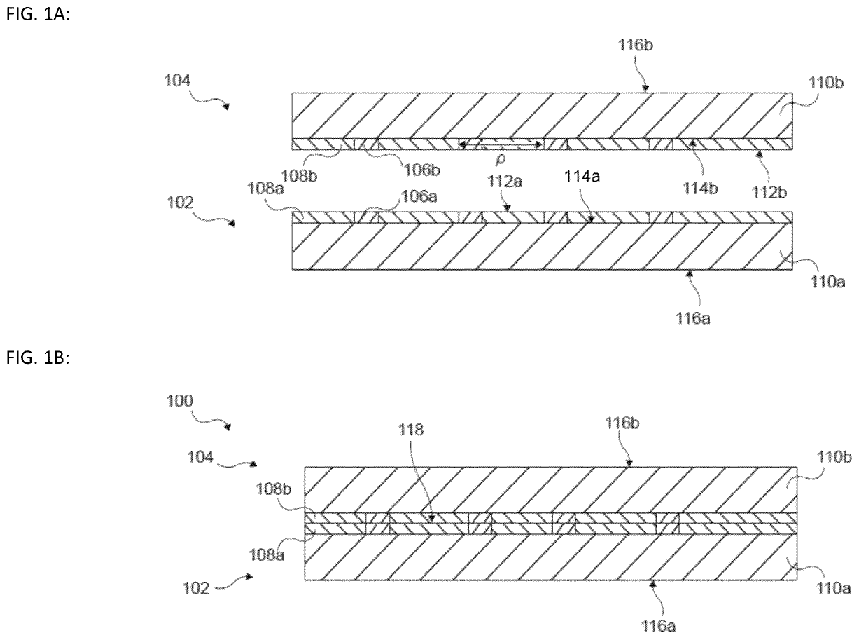

FIGS. 1A and 1B schematically illustrate cross-sectional side views of first and second elements 102, 104 prior to and after, respectively, a process for forming a directly bonded structure, and more particularly a hybrid bonded structure, according to some implementations. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated implementation are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some implementations, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other implementations, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some implementations, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some implementations, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other implementations, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other implementations, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other implementations such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The implementations disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some implementations, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some implementations, one or both of the surfaces 112a, 112b can be terminated with a species after activation or during activation (e.g., during the plasma and/or etch processes). Without being limited by theory, in some implementations, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some implementations, the activation and termination are provided in the same step, e.g., a plasma to activate and terminate the surface(s) 112a, 112b. In other implementations, one or both of the bonding surfaces 112a, 112b can be terminated in a separate treatment to provide the additional species for direct bonding. In various implementations, the terminating species can comprise nitrogen. For example, in some implementations, the bonding surface(s) 112a, 112b can be exposed to a nitrogen-containing plasma. Other terminating species can be suitable for improving bonding energy, depending upon the materials of the bonding surfaces 112a, 112b. Further, in some implementations, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some implementations, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some implementations, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some implementations, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some implementations, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding implementations, opposing conductive materials are joined without heating above the conductive materials' melting temperature, such that bonds can form with lower anneal temperatures compared to soldering or thermocompression bonding.

In various implementations, the conductive features 106a, 106b can comprise discrete pads, contacts, electrodes, or traces at least partially embedded in the non-conductive field regions of the bonding layers 108a, 108b. In some implementations, the conductive features 106a, 106b can comprise exposed contact surfaces of TSVs (e.g., through silicon vias).

As noted above, in some implementations, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some implementations, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various implementations, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated implementation, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some implementations, the materials of the conductive features 106a, 106b of opposite elements 102, 104 can interdiffuse during the annealing process. In some implementations, metal grains grow into each other across the bond interface 118. In some implementations, the metal is or includes copper, which can have grains oriented along the 111 crystal plane for improved copper diffusion across the bond interface 118. In some implementations, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some implementations, a barrier layer may be provided under and/or laterally surrounding the conductive features 106a and 106b (e.g., which may include copper). In other implementations, however, there may be no barrier layer under the conductive features 106a and 106b.

Certain implementations disclosed herein relate to optoelectronic devices that include directly bonded contacts comprising optically transparent or optically semi-transparent electrically conducting material (referred to herein collectively as transparent conductors or TCs) instead of metal direct bonded contacts. For example, the optoelectronic devices can include optical elements or devices (e.g., photodiodes; light emitting diodes (LEDs)); quantum dot light emitting diodes (QLEDs); lasers; vertical-cavity surface-emitting lasers (VCSELs); transparency control pixels; liquid crystal pixels; adaptive optics; solar cells; waveguides; spatial light modulators; diode lasers; electrochromic devices) that are stacked on or bonded to one another to form a bonded structure. The TCs on separate substrates can be planarized and the planarized surfaces of the substrates can be placed in contact with one another, as described herein, to form the bonded structures.

In certain implementations, the optoelectronic devices described herein are configured to be used in various contexts which are area-limited (e.g., displays for virtual reality (VR) or augmented reality (AR) applications; multijunction solar cells) or other designs comprising an optoelectronic (e.g., electro-optical) element within a stack of other optical elements, beneficially utilizing the TCs for providing electrical connection between electrical elements while not appreciably blocking light. In certain implementations, the optoelectronic devices described herein are termed as co-packaged optics (CPO) in which several optical elements are packaged together and interact with at least one processor (e.g., GPU, CPU, NPU), network switch, or memory package attached to an interposer used in high performance computer applications geared towards data centers.

As used herein, the term “optically transparent” includes but is not limited to optically translucent, optically semi-transparent, and/or having an optical transmittance of at least 50% (e.g., at least 60%; at least 75%; at least 88%; greater than or equal to 95%) at optical wavelengths in a predetermined range. For example, the predetermined range for optically transparent components (e.g., elements; substrates; layers; devices; features) can be visible wavelengths (e.g., 390 nanometers to 750 nanometers; 400 nanometers to 700 nanometers), ultraviolet wavelengths (e.g., 100 nanometers to 400 nanometers), infrared wavelengths (e.g., 800 nanometers to 1 millimeter), and/or short-wave infrared (SWIR) wavelengths (e.g., 1400 nanometers to 3000 nanometers).

As described herein, some electrically conductive oxides (e.g., indium tin oxide or ITO) or nitrides have the ability to self-bond (e.g., direct bonding between similar materials) at modest temperatures (e.g., in a range of 75° C. to 400° C.; in a range of 120° C. to 300° C.; in a range of 150° C. to 300° C.). In certain implementations, use of electrically conductive oxide or nitride layers can simplify processes for bonding (e.g., blanket wafer and hybrid bonding surfaces) by omitting one or more other processing steps (e.g., planarization and/or surface activation). For example, the electrically conductive oxide or nitride layers can be self-leveled if planarized before patterning. In conjunction with certain layout structures, such electrically conductive oxide or nitride layers can be used to bond multiple input/output components with a single material interface. For example, ITO can be used to bond two substrates without a surface activation step, and in certain implementations, without a surface planarization (e.g., chemical-mechanical polishing or CMP) step. The electrically conductive oxide or nitride layers can also allow bonding at modest temperatures (e.g., less than 300° C.) and can be used for surface mounting. In view of the electrical conductivity, such layers can provide electromagnetic shielding for other components of the electronic packages. In addition, because certain such materials are substantially optically transparent, they can be used for bonding optoelectronic applications, as well as in other structures where photon transmission is not a factor.

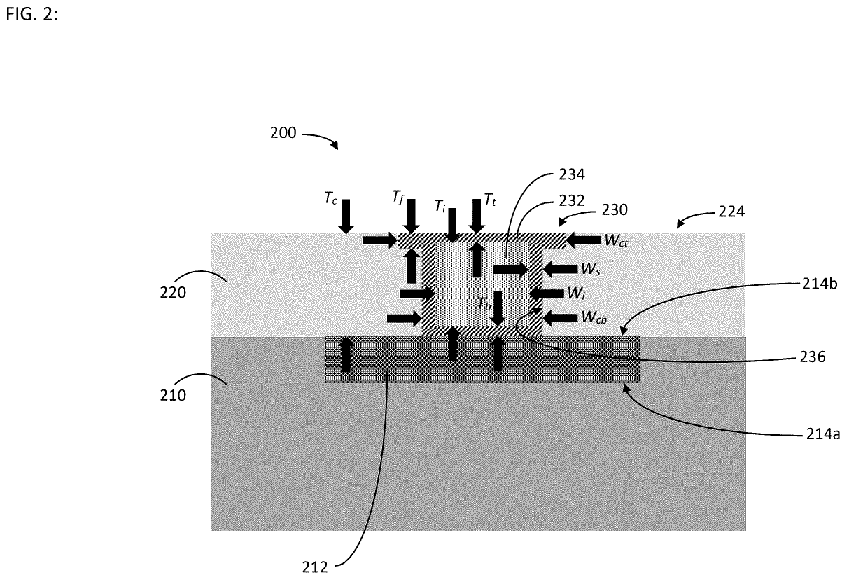

FIG. 2 schematically illustrates a cross-sectional view of an example structure 200 in accordance with certain implementations described herein. The structure 200 (e.g., first element 102; second element 104 as shown in FIG. 1) comprises a substrate 210 comprising a device 212 having first and second sides 214a,b generally opposite to one another. The structure 200 further comprises at least one dielectric layer 220 at least partially overlying the second side 214b of the device 212. The structure 200 further comprises a conduit 230 (e.g., via; first conductive feature 106a) extending through the at least one dielectric layer 220 configured to transmit electrical signals and optical signals (e.g., light) through the at least one dielectric layer 220 to the device 212 and/or from the device 212. The conduit 230 comprises an electrically conductive and optically transmissive first portion 232 and an electrically insulative and optically transmissive second portion 234. The first portion 232 is in electrical communication with the second side 214b of the device 212 and substantially overlies the second portion 234. For example, the structure 200 can comprise one or dielectric layers and electrically conductive interconnects between the bottom of the first portion 232 and the second side 214b. In certain implementations, the second side 214b is not an abrupt interface, but is a region having an impurity doping gradient between the substrate 210 and the device 212.

In certain implementations, the substrate 210 comprises one or more semiconductor layers (e.g., Si), one or more electrically insulative layers (e.g., SiOₓ), and/or one or more electrically conductive layers (e.g., Cu, which can be patterned and at least partially embedded in the one or more electrically insulative layers). In certain implementations, the at least one dielectric layer 220 comprises at least one dielectric material (e.g., an inorganic dielectric material), examples of which include, but are not limited to: semiconductor oxides; semiconductor nitrides; silicon oxide (SiOₓ; SiO₂); silicon nitride (SiNₓ, Si₃N₄); silicon oxycarbonitride (SiOₓN_{y}C_{z}); titanium oxide; silicon carbonitride (SiCN); etc. The device 212 can comprise one or more layers of the substrate 210 and can be optically transparent, optically translucent, or optically opaque. Examples of the device 212 include but are not limited to: light-emitting diode (LED); laser diode; laser; optical waveguide; electro-optical sensor; optoelectronic device; optoelectronic element; electro-optical element; solar cell; electrical conduit (e.g., optically transparent; optically translucent; optically opaque). For example, the electrical conduit can comprise a metal (e.g., Cu; Al), a metal alloy (e.g., Cu alloy; Al alloy), or a transparent conductive oxide (TCO).

In certain implementations, the first portion 232 of the conduit 230 comprises at least one electrically conductive and optically transmissive material, examples of which include but are not limited to: aluminum zinc oxide (AZO); indium tin oxide (ITO, InSnO₃, In₂O₃); zinc oxide (ZnO); zinc tin oxide (ZnSnO₃, Zn₂SnO₄); indium-doped zinc oxide (IZO); indium oxide; cadmium tin oxide (Cd₂SnO₄); tin oxide (SnO₂); fluorine-doped tin oxide; titanium dioxide (TiO₂); niobium-doped titanium dioxide (Nb—TiO₂); other electrically conductive oxide materials; titanium nitride (TiN); tin nitride (Sn₃N₄); other metal nitrides (e.g., A₃N₂ where A=Mg, Zn, Sn); other transition metal nitrides comprising a IIIB, IVB, or VB transition metal. In certain implementations, the resistivity of the at least one electrically conductive and optically transmissive material is in a range less than 1×10⁻² Ω-cm (e.g., less than 500×10⁻⁶ Ω-cm; 200×10⁻⁶ Ω-cm to 40×10⁻⁶ Ω-cm; 500×10⁻⁶ Ω-cm to 20×10⁻⁶ Ω-cm; in a range less than 120×10⁻⁶ Ω-cm).

In certain implementations, the second portion 234 of the conduit 230 comprises at least one electrically insulative and optically transmissive material, examples of which include but are not limited to: aluminum oxide (e.g., Al₂O₃; alumina); other dielectric metal oxides; aluminum nitride (e.g., AlN); other metal nitrides. Thus, the first portion 232 can have a higher electrical conductivity than does the second portion 234. Each of the first portion 232 and/or the second portion 234 can comprise a single layer of a single material or multiple layers of different materials. In certain implementations, the optical transmission of each of the first portion 232 and the second portion 234 in the wavelength range of interest (e.g., a wavelength range of operation of the device 212) is greater than 40% (e.g., greater than 60%; greater than 80%). In certain implementations, the second portion 234 is embedded within the first portion 232 (e.g., the first portion 232 substantially surrounds or extends around all sides of the second portion 234).

In certain implementations, an outer surface of the first portion 232 extends to an outer surface 224 of the at least one dielectric layer 220. In certain other implementations, the outer surface of the first portion 232 can be recessed (e.g., in a range of 3 nm to 40 nm; in a range of 2 nm to 8 nm; by less than 10 nm) relative to the outer surface 224 of the at least one dielectric layer 220. The recess of the first portion 232 relative to the outer surface 224, the thicknesses Tₜ of the first portion 232, and the thickness Tᵢ of the second portion 234 can account for the differing coefficients of thermal expansion (CTE) of the electrically conductive and optically transmissive material of the first portion 232, the electrically insulative and optically transmissive material of the second portion 234, and the material of the at least one dielectric layer 220 (e.g., differing amounts of thermal expansion in a direction perpendicular to the top surfaces during subsequent annealing). For example, the CTE of ITO is about 5.8×10⁻⁶/K to 9×10⁻⁶/K and the CTE of Al₂O₃ is about 8.4×10⁻⁶/K to 12.7×10⁻⁶/K, while the CTE of silicon oxide is about 0.5×10⁻⁶/K. For comparison, the CTE of Cu is about 16.7×10⁻⁶/K. In certain other implementations, the outer surface of the first portion 232 can protrude (e.g., in a range of less than 2 nm) relative to the outer surface 224 of the at least one dielectric layer 220. With the outer surface of the first portion 232 protruding relative to the outer surface 224, the CTE of the material of the first portion 232 can be equal to or greater than the CTE of the material of the second portion 234. Having the CTE of the material of the second portion 234 greater than the CTE of the material of the first portion 232 can result in additional pressure that facilitates bonding of the conductive elements at lower temperatures and/or facilitates stronger bonding at a predetermined temperature.

In FIG. 2, various widths and thicknesses of the conduit 230, the first portion 232, and the second portion 234 in a cross-sectional plane substantially perpendicular to the outer surface 224 are shown by pairs of oppositely facing arrows. Each of the conduit 230, the first portion 232, and the second portion 234 can have a cross-sectional shape in a plane substantially parallel to the outer surface 224, with examples of the cross-sectional shape including but are not limited to: rectangular, square, circular, oval, polygonal, symmetric, asymmetric. In certain implementations, the cross-sectional shape and/or size of one or more of the conduit 230, first portion 232, and second portion 234 is substantially constant as a function of depth below the outer surface 224, while in certain other implementations, the cross-sectional shape and/or size of one or more of the conduit 230, first portion 232, and second portion 234 varies as a function of depth below the outer surface 224.

In certain implementations, the conduit 230 has a width W_{c} in a range of 500 nm to 100 microns along a first direction substantially parallel to the outer surface 224. While in certain implementations, the width W_{c} of the conduit 230 is substantially uniform from the second side 214b to the outer surface 224, in certain other implementations, different regions of the conduit 230 have different widths W_{c}. For example, as shown in FIG. 2, the conduit 230 can comprise a top region and a bottom region, the top region extending to the outer surface 224 and having a width W_{ct} and the bottom region extending to the second side 214b and having a width W_{cb} less than W_{ct}. One or both of the widths W_{ct} and W_{cb} can be in a range of 500 nm to 100 microns.

In certain implementations, the second portion 234 has a width Wᵢ in a range of 0.2 micron to 100 microns (e.g., in a range of 0.2 micron to 5 microns) along the first direction substantially parallel to the outer surface 224, with the width Wᵢ less than W_{c}. In addition, the first portion 232 along the sidewalls 236 of the conduit 230 (e.g., between the sidewalls 236 and the second portion 234) has a width Wₛ in a range of 0.1 micron to 20 microns along the first direction. In certain implementations, the width Wₛ is larger than the width Wᵢ. The width Wₛ is sufficiently large such that the first portion 232 along the sidewalls 236 provides sufficient electrical conductance to allow electrical signals to be transmitted between the outer surface of the first portion 232 and the second side 214b of the device 212. In certain implementations, the width W₁ of the second portion 234 and the width Wₛ of the first portion 232 are substantially uniform (see, e.g., FIG. 2) from the bottom region to the top region, while in certain other implementations, the second portion 234 in the top and bottom regions have different widths Wᵢ and the first portion 232 in the top and bottom regions have different widths Wₛ In addition, while in certain implementations, the second portion 234 is centered within the conduit 230 along the first direction substantially parallel to the outer surface 224 such that the widths Wₛ of the first portion 232 along opposite sidewalls 236 of the conduit 230 are substantially equal to one another (see, e.g., FIG. 2), in certain other implementations, the second portion 234 is offset from the center of the conduit 230 along the first direction such that the widths Wₛ of the first portion 232 along opposite sidewalls 236 of the conduit 230 are substantially different from one another.

In certain implementations, the conduit 230 has a thickness T_{c} in a range of 0.1 micron to 100 microns (e.g., 1 micron to 100 microns; 2 microns to 100 microns) along a second direction substantially perpendicular to the outer surface 224 (e.g., the thickness T_{c} substantially equal to a thickness of the at least one dielectric layer 220). While in certain implementations, the thickness T_{c} of the conduit 230 is substantially uniform from the second side 214b to the outer surface 224 (see, e.g., FIG. 2), in certain other implementations, the thickness T_{c} is non-uniform.

In certain implementations, the bottom region of the first portion 232 (e.g., between the second side 214b and the second portion 234) has a thickness T_{b} (e.g., in a range of less than or equal to 0.3 micron; in a range of 0.1 micron to 5 microns; in a range of 1 micron to 2 microns) along a second direction substantially perpendicular to the outer surface 224. While in certain implementations, the thickness T_{b} is substantially uniform across the second portion 234 (see, e.g., FIG. 2), in certain other implementations, the thickness T_{b} is non-uniform. In certain implementations, the thickness T_{b} of the first portion 232 at the bottom region of the conduit 230 is at least twice the width Wₛ of the first portion 232 along the sidewalls 236 of the conduit 230.

In certain implementations, the top region of the first portion 232 (e.g., between the outer surface 224 and the second portion 234) has a thickness Tₜ (e.g., in a range of less than or equal to 0.3 micron; in a range of 0.1 micron to 5 microns; in a range of 1 micron to 2 microns) along the second direction substantially perpendicular to the outer surface 224. While in certain implementations, the thickness Tₜ is substantially uniform across the second portion 234 (see, e.g., FIG. 2), in certain other implementations, the thickness Tₜ is non-uniform. While FIG. 2 shows a thickness Tₜ that is non-zero (e.g., the first portion 232 completely covering the second portion 234), in certain other implementations, Tₜ can be substantially equal to zero, such that the top of the second portion 234 is exposed and forms part of the outer surface 224 with the first portion 232 forming a collar (e.g., on the sidewall 236 and forming part of the outer surface 224) configured to provide electrical conductivity between the device 212 and the outer surface 224).

In certain implementations in which the width W_{ct} of the top region of the conduit 230 is greater than the width W_{cb} of the bottom region of the conduit 230 (see, e.g., FIG. 2), the top region of the conduit 230 comprises flange regions (e.g., offset from the second portion 234 in the first direction substantially parallel to the outer surface 224) which have a thickness T_{f} in a range of 0.3 micron to 5 microns (e.g., in a range of 1 micron to 2 microns) along the second direction and are filled by the at least one substantially transparent first material of the first portion 232. In certain implementations, T_{f} is greater than Tₜ (see, e.g., FIG. 2), while in certain other implementations, T_{f} is less than or equal to Tₜ. The flange regions can be configured to facilitate bonding of the conduit 230 with another structure (e.g., by increasing the surface area of the conduit 230 that is to be bonded to the other structure).

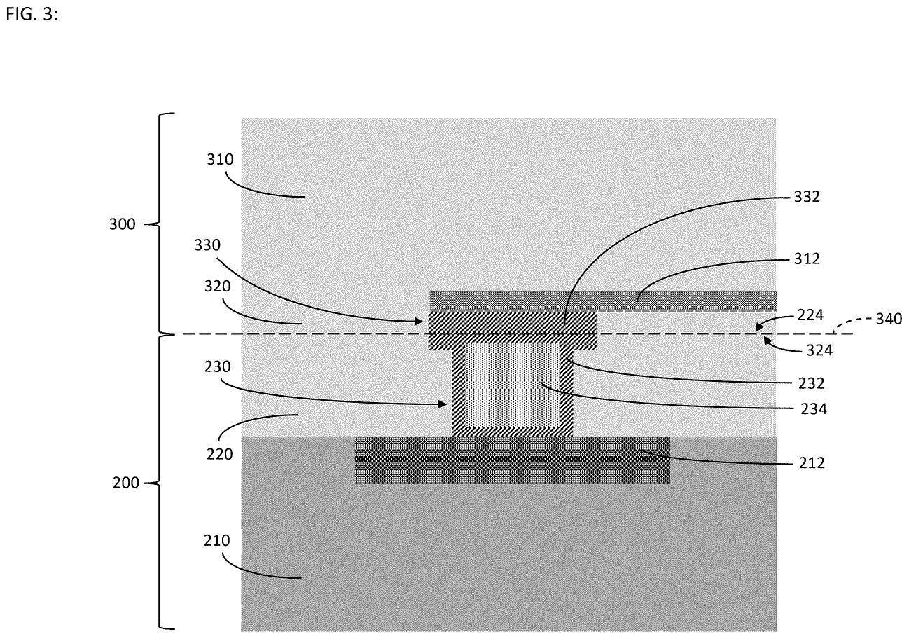

In certain implementations, the structure 200 is configured to be bonded (e.g., directly bonded; hybrid bonded) to another structure with the conduit 230 bonded to a corresponding portion of another structure and the electrically insulative portions of the outer surface 224 bonded to corresponding portions of the other structure. FIG. 3 schematically illustrates a cross-sectional view of the structure 200 bonded to a second structure 300 (e.g., second element 104) in accordance with certain implementations described herein. As described herein with regard to the structure 200, the second structure 300 can comprise a second substrate 310 comprising a second device 312. The second structure 300 can further comprise at least one second dielectric layer 320 at least partially overlying the second device 312. The second structure 300 can further comprise a second conduit 330 (e.g., conductive feature 106b) extending through the at least one second dielectric layer 320 configured to transmit electrical signals and/or optical signals through the at least one second dielectric layer 320 to the second device 312 and/or from the second device 312. The second conduit 330 comprises an electrically conductive and optically transmissive material 332 in electrical communication with the second device 312 and extends to a second outer surface 324 of the at least one second dielectric layer 320. The structure 200 and the second structure 300 can be bonded to one another in accordance with the disclosure of U.S. patent application Ser. No. 18/391,173, entitled “Conductive Materials for Direct Bonding,” filed Dec. 20, 2023 and incorporated in its entirety by reference herein. In certain implementations, the conduit 230 and the second conduit 330 are substantially transparent and the device 212 and the second device 312 are not substantially transparent (e.g., the second device 312 can block light emitted upwards from the second side 214b of the device 212). In certain such implementations, the substantially transparent conduit 230, second conduit 330, and/or optically transmissive material 332 are configured to laterally offset the second device 312 from the device 212 such that light emitted upwards from the second side 214b of the device 212 is not substantially blocked by the second device 312. For example, this offset can be achieved via reconstitution where the second device 312 is on a reconstituted wafer and a portion of the reconstituted wafer above the device 212 is substantially transparent, such that light passes through the conduit 230, second conduit 330 and the optically transmissive material 332 of the reconstituted wafer.

Examples of the second substrate 310, second device 312, at least one second dielectric layer 320, second conduit 330, and electrically conductive and optically transmissive material 332 are the same as the examples of the substrate 210, device 212, at least one first dielectric layer 220, conduit 230, and electrically conductive and optically transmissive first portion 232, respectively, as described herein. For example, dielectric portions of the second outer surface 324 of the second structure 300 can have the same material as dielectric portions of the outer surface 224 and electrically conductive portions of the second outer surface 324 of the second structure 300 can have the same material as the electrically conductive portions of the outer surface 224 (e.g., the first portion 232 of the conduit 230 of the structure 200). The second conduit 330 can comprise the same electrically conductive and optically transmissive material as that of the first portion 232 of the conduit 230 (e.g., the bonding of the conduit 230 and the second conduit 330 can comprise direct bonding) or can comprise a different electrically conductive and optically transmissive material (e.g., material having different elemental constituents and/or different stoichiometries) from that of the first portion 232 of the conduit 230 (e.g., the bonding of the conduit 230 and the second conduit 330 can comprise hybrid bonding).

As shown in FIG. 3, the bonding of dielectric portions of the outer surface 224 with dielectric portions of the second outer surface 324 and the bonding of the conduit 230 at the outer surface 224 with the second conduit 330 at the second outer surface 324 can form an interface layer 340 between the structure 200 and the second structure 300 (e.g., formed by direct bonding of two opposing layers of at least one electrically conductive oxide material). Once bonded to one another, the electrically conductive and optically transmissive material of the first portion 232 of the conduit 230 and the electrically conductive and optically transmissive material 332 of the second conduit 330 allows transmission of both electrical and/or optical signals through the interface layer 340 between the device 212 and the second device 312. The electrically insulative and optically transmissive material of the second portion 234 also allows transmission of optical signals between the device 212 and the second device 312.

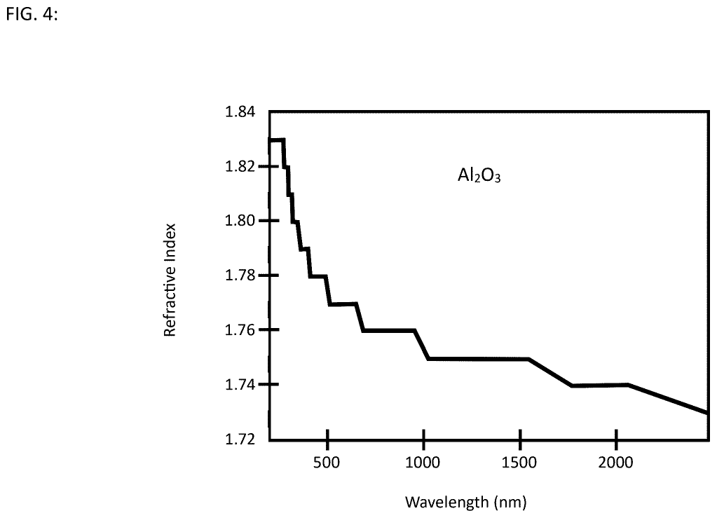

In certain implementations, at wavelengths in the visible wavelength range (e.g., at a wavelength of operation of the device 212), the electrically insulative and optically transmissive material of the second portion 234 has a refractive index that is substantially equal to (e.g., within ±10% of) the refractive index of the electrically conductive and optically transmissive material of the first portion 232. For example, FIG. 4 is a plot of the refractive index of Al₂O₃ as a function of wavelength in a range of about 200 nm to about 2500 nm in accordance with certain implementations described herein. At a wavelength of 633 nm, the refractive index of Al₂O₃ is approximately 1.77 and the refractive index of ITO is approximately 1.86. In certain implementations, at wavelengths in the visible wavelength range (e.g., at a wavelength of operation of the device 212), the electrically insulative and optically transmissive material of the second portion 234 has an optical extinction coefficient that is less than an optical extinction coefficient of the electrically conductive and optically transmissive material of the first portion 232. For example, at a wavelength of 633 nm, the optical extinction coefficient of Al₂O₃ is approximately zero and the optical extinction coefficient of ITO is approximately 0.058.

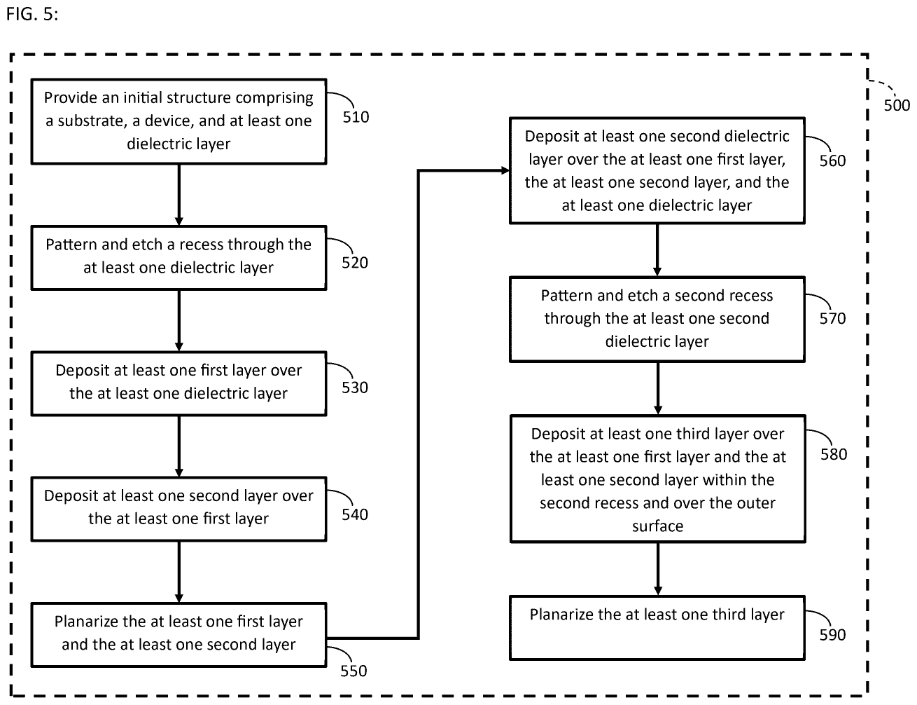

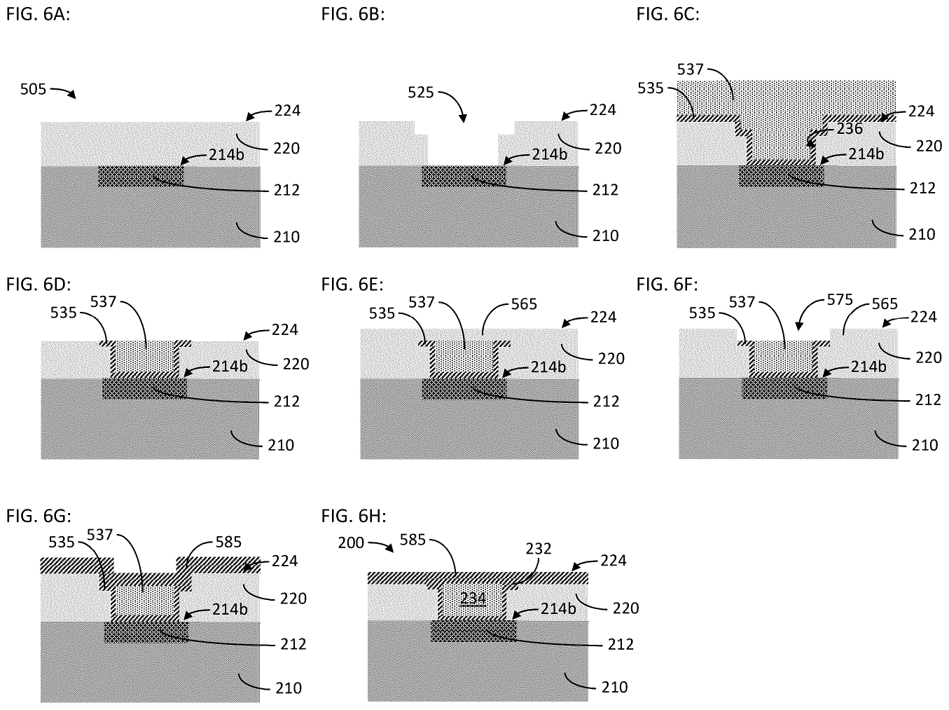

FIG. 5 is a flow diagram of an example method 500 for forming a structure 200 compatible with certain implementations described herein. FIGS. 6A-6H schematically illustrate various structures formed during an example method 500 forming the example structure 200 of FIG. 2 in accordance with certain implementations described herein. While the example method 500 is described herein by referring to the example structure 200 of FIGS. 2 and 6A-6H, other structures are also compatible with the example method 500 in accordance with certain implementations described herein.

In an operational block 510, the method 500 comprises providing an initial structure 505 comprising the substrate 210, the device 212 (e.g., LED) having the first and second sides 214a, 214b generally opposite to one another, and the at least one dielectric layer 220 overlying the substrate and the second side 214b of the device 212. For example, the initial structure 505 can comprise an LED wafer or a discrete LED bonded to a driver substrate with one or more overlying inorganic dielectric layers 220 (e.g., oxide, SiO₂, nitride). FIG. 6A schematically illustrates a cross sectional view of an example initial structure 505 in accordance with certain implementations described herein.

In an operational block 520, the method 500 further comprises patterning (e.g., using photolithographic techniques) and etching a recess 525 (e.g., hole) through the at least one dielectric layer 320 extending from the outer surface 224 of the at least one dielectric layer 220 to the second side 214b of the device 212. In certain implementations, the patterning and etching of the recess 525 can be performed using a single damascene process or a dual damascene process. The etching can comprise directional RIE, wet etching, or dry etching. FIG. 6B schematically illustrates a cross sectional view of an example recess 525 in accordance with certain implementations described herein.

In an operational block 530, the method 500 further comprises depositing at least one first layer 535 comprising at least one electrically conductive and optically transmissive material (e.g., ITO) over the at least one dielectric layer 220 (e.g., onto the outer surface 224), over the device 212 (e.g., onto the second side 214b within the recess 525), and onto the sidewalls 236 within the recess 525. In an operational block 540, the method 500 further comprises depositing at least one second layer 537 comprising at least one electrically insulative and optically transmissive material (e.g., Al₂O₃) over the at least one first layer 535. Examples of deposition processes for depositing the at least one first layer 535 and/or depositing the at least one second layer 537 include but are not limited to: sputtering, activated chemical vapor deposition (CVD), directional physical vapor deposition (PVD), or atomic layer deposition (ALD). FIG. 6C schematically illustrates a cross sectional view of an example first layer 535 and second layer 537 in accordance with certain implementations described herein.

In an operational block 550, the method 500 further comprises planarizing the at least one first layer 535 and the at least one second layer 537. For example, the at least one first layer 535 and the at least one second layer 537 can be planarized using CMP (e.g., with a CMP rate of 50-60 nm/min for the at least one first layer 535 comprising ITO). The electrically insulative and optically transmissive material of the at least one second layer 537 (e.g., Al₂O₃) can be harder than the electrically conductive and optically transmissive material of the at least one first layer 535 (e.g., ITO), and can be harder than the at least one dielectric layer 220 (e.g., SiOₓ), such that the CMP rate for the at least one second layer 537 dictates the speed of this planarization step. FIG. 6D schematically illustrates a cross sectional view of the example first layer 535 and second layer 537 after planarization in accordance with certain implementations described herein. In certain implementations, the electrically insulative and optically transmissive material of the at least one second layer 537 is harder (e.g., more resistant to planarization) than are either the electrically conductive and optically transmissive material of the at least one first layer 535 or the at least one dielectric layer 220, and the rate of planarization to get the structure shown in FIG. 6D is dependent on the rate of planarization of the electrically insulative and optically transmissive material.

In an operational block 560, the method 500 further comprises depositing at least one second dielectric layer 565 over (e.g., onto) the at least one first layer 535, the at least one second layer 537, and the at least one dielectric layer 220 (e.g., onto the outer surface 224, thereby forming a new outer surface 224). The at least one second dielectric layer 565 can comprises an inorganic dielectric material, examples of which include, but are not limited to: semiconductor oxides; semiconductor nitrides; silicon oxide (SiOₓ; SiO₂); silicon nitride (SiNₓ, Si₃N₄); silicon oxycarbonitride (SiOₓN_{y}C_{z}); titanium oxide. In certain implementations, the at least one second dielectric layer 565 comprises the same inorganic dielectric material as does the at least one dielectric layer 220 (e.g., SiOₓ or SiO₂). Examples of deposition processes for depositing the at least one second dielectric layer 565 include but are not limited to: sputtering, activated chemical vapor deposition (CVD), directional physical vapor deposition (PVD), or atomic layer deposition (ALD). FIG. 6E schematically illustrates a cross sectional view of an example second dielectric layer 565 in accordance with certain implementations described herein.

In an operational block 570, the method 500 further comprises patterning (e.g., using photolithographic techniques) and etching a second recess 575 (e.g., hole) through the at least one second dielectric layer 565 extending from the outer surface 224 of the at least one second dielectric layer 565 to the at least one first layer 535 and the at least one second layer 537. In certain implementations, the patterning and etching of the second recess 575 can be performed using a single damascene process or a dual damascene process. The etching can comprise directional RIE, wet etching, or dry etching. FIG. 6F schematically illustrates a cross sectional view of an example second recess 575 in accordance with certain implementations described herein.

In an operational block 580, the method 500 further comprises depositing at least one third layer 585 comprising at least one electrically conductive and optically transmissive material (e.g., ITO) over (e.g., onto) the at least one first layer 535 and the at least one second layer 537 within the second recess 575 and over (e.g., onto) the outer surface 224 of the at least one second dielectric layer 565. In certain implementations, the at least one third layer 585 comprises the same electrically conductive and optically transmissive material as does the at least one first layer 535 (e.g., ITO). Examples of deposition processes for depositing the at least one third layer 585 include but are not limited to: sputtering, activated CVD, directional PVD, or ALD. FIG. 6G schematically illustrates a cross sectional view of an example third layer 585 in accordance with certain implementations described herein.

In an operational block 590, the method 500 further comprises planarizing the at least one third layer 585. For example, the at least one third layer 585 can be planarized using CMP. FIG. 6H schematically illustrates a cross sectional view of the example third layer 585 after planarization in accordance with certain implementations described herein. The operational blocks 570, 580, and 590 are used to have the top surface of the at least one second layer 537 recessed below the outer surface 224 of the at least one dielectric layer 220 in certain implementations in which the electrically insulative and optically transmissive material of the at least one second layer 537 (e.g., Al₂O₃) is harder than the at least one dielectric layer 220 (e.g., SiOₓ).

The electrically conductive and optically transmissive first portion 232 of the conduit 230 comprises the at least one first layer 535 within the recess 525 and the at least one third layer 585 within the second recess 575, and the electrically insulative and optically transmissive second portion 234 of the conduit 230 comprises the at least one second layer 537. The structure 200 fabricated by the method 500 can be ready for bonding to a second structure 300 as described herein with regard to FIG. 3. In certain implementations, the electrically insulative and optically transmissive material of the second portion 234 provides additional thickness for enhanced thermal expansion during an anneal process while providing a lower optical extinction coefficient than does the electrically conductive and optically transmissive material (e.g., ITO) of the first portion 232.

In certain implementations, the at least one third layer 585 is directly bonded with a conductive feature of another structure without an intervening adhesive. For example, directly bonding the at least one third layer and the conductive feature can comprises contacting the at least one third layer 585 and the conductive feature with one another. In certain implementations, at least one of the at least one third layer 585 and the conductive feature are cleaned prior to contacting the at least one third layer 585 and the conductive feature with one another.

Although commonly used terms are used to describe the systems and methods of certain implementations for ease of understanding, these terms are used herein to be interpreted fairly. Although various aspects of the disclosure are described with regard to illustrative examples and implementations, the disclosed examples and implementations should not be construed as limiting. Conditional language, such as, among others, “can,” “could,” “might,” or “may,” unless specifically stated otherwise, or otherwise understood within the context as used, is generally intended to convey that certain implementations include, while other implementations do not include, certain features, elements and/or steps. Thus, such conditional language is not generally intended to imply that features, elements and/or steps are in any way required for one or more implementations or that one or more implementations necessarily include logic for deciding, with or without user input or prompting, whether these features, elements and/or steps are included or are to be performed in any particular implementation. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

It is to be appreciated that the implementations disclosed herein are not mutually exclusive and may be combined with one another in various arrangements. In addition, although the disclosed methods and apparatuses have largely been described in the context of direct bonding processes, various implementations described herein can be incorporated in a variety of other suitable devices, methods, and contexts.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. As another example, the terms “generally parallel” and “substantially parallel” refer to a value, amount, or characteristic that departs from exactly parallel by ±10 degrees, by ±5 degrees, by ±2 degrees, by ±1 degree, or by ±0.1 degree, and the terms “generally perpendicular” and “substantially perpendicular” refer to a value, amount, or characteristic that departs from exactly perpendicular by ±10 degrees, by ±5 degrees, by ±2 degrees, by ±1 degree, or by ±0.1 degree. The ranges disclosed herein also encompass any and all overlap, sub-ranges, and combinations thereof. Language such as “up to,” “at least,” “greater than,” less than,” “between,” and the like includes the number recited. As used herein, the meaning of “a,” “an,” and “said” includes plural reference unless the context clearly dictates otherwise. Also, as used in the description herein, the meaning of “in” includes “into” and “on,” unless the context clearly dictates otherwise.

While the methods and systems are discussed herein in terms of elements labeled by ordinal adjectives (e.g., first, second, etc.), the ordinal adjective are used merely as labels to distinguish one element from another (e.g., one substrate from another or one surface layer from one another), and the ordinal adjective is not used to denote an order of these elements or of their use.

The disclosure described and claimed herein is not to be limited in scope by the specific example implementations herein disclosed, since these implementations are intended as illustrations, and not limitations, of several aspects of the disclosure. Any equivalent implementations are intended to be within the scope of this disclosure. Indeed, various modifications of the disclosure in form and detail, in addition to those shown and described herein, will become apparent to those skilled in the art from the foregoing description. Such modifications are also intended to fall within the scope of the claims. The breadth and scope of the disclosure should not be limited by any of the example implementations disclosed herein, but should be defined only in accordance with the claims and their equivalents.

1. A structure comprising:
a substrate comprising a device having first and second sides generally opposite to one another;
at least one dielectric layer at least partially overlying the second side of the device; and
a conduit extending through the at least one dielectric layer, to transmit electrical signals and light through the at least one dielectric layer to and/or from the device, the conduit comprising:
an electrically conductive and optically transmissive first portion; and
an electrically insulative and optical transmissive second portion, the first portion in electrical communication with the second side of the device and substantially overlying the second portion.

2. The structure of claim 1, wherein the substrate comprises one or more semiconductor layers, one or more electrically insulative layers, and/or one or more electrically conductive layers.

3. The structure of claim 1, wherein the at least one dielectric layer comprises at least one dielectric material selected from the group consisting of: semiconductor oxides; semiconductor nitrides; silicon oxide (SiOₓ; SiO₂); silicon nitride (SiNₓ, Si₃N₄); silicon carbonitride (SiCN); silicon oxycarbonitride (SiOₓN_{y}C_{z}); titanium oxide.

4. The structure of claim 1, wherein the device is selected from the group consisting of: light-emitting diode (LED); laser diode; laser; optical waveguide; electro-optical sensor; optoelectronic device; optoelectronic element; electro-optical element; solar cell; electrical conduit.

5. The structure of claim 1, wherein the first portion of the conduit comprises at least one electrically conductive and optically transmissive material.

6. The structure of claim 5, wherein the at least one electrically conductive and optically transmissive material is optically transparent.

7. The structure of claim 5, wherein the at least one electrically conductive and optically transmissive material is selected from the group consisting of: aluminum zinc oxide; indium tin oxide; zinc oxide; zinc tin oxide; indium-doped zinc oxide; indium oxide; cadmium tin oxide; tin oxide; titanium dioxide; niobium-doped titanium dioxide; other electrically conductive oxide materials; titanium nitride; tin nitride; other metal nitrides.

8. The structure of claim 1, wherein the second portion of the conduit comprises at least one electrically insulative and optically transmissive material.

9. The structure of claim 8, wherein the at least one electrically insulative and optically transmissive material is optically transparent.

10. The structure of claim 8, wherein the at least one electrically insulative and optically transmissive material is selected from the group consisting of: aluminum oxide; other dielectric metal oxides; aluminum nitride; other metal nitrides.

11. The structure of claim 1, wherein the first portion comprises indium tin oxide and the second portion comprises aluminum oxide.

12. The structure of claim 1, wherein each of the first portion and the second portion have an optical transmission greater than 40% in a wavelength range of operation of the device.

13. The structure of claim 1, wherein an outer surface of the first portion is recessed relative to an outer surface of the at least one dielectric layer.

14. The structure of claim 1, wherein the conduit has a first width in a range of 500 nm to 2 millimeters along a first direction substantially parallel to an outer surface of the at least one dielectric layer.

15. The structure of claim 14, wherein the second portion of the conduit has a second width in a range of 500 nm to 2 millimeters along the first direction, the second width less than the first width.

16. The structure of claim 15, wherein the conduit comprises a top region and a bottom region, the top region extending to an outer surface of the first portion and having a third width along the first direction substantially parallel to the outer surface of the at least one dielectric layer and the bottom region extending to the second side and having a fourth width along the first direction, the fourth width less than the third width.

17. The structure of claim 16, wherein the first portion between sidewalls of the conduit and the second portion has a fifth width along the first direction substantially parallel to the outer surface of the at least one dielectric layer, the fifth width sufficiently large such that the first portion provides sufficient electrical conductance to allow electrical signals to be transmitted between the outer surface of the first portion and the second side of the device.

18. The structure of claim 1, wherein the conduit has a thickness in a range of 0.1 micron to 100 microns along a second direction substantially perpendicular to an outer surface of the at least one dielectric layer.

19. The structure of claim 1, wherein the second portion is embedded within the first portion.

20. The structure of claim 1, wherein the structure comprises a second structure hybrid bonded to the at least one dielectric layer and the conduit.

21.-36. (canceled)
